(19) United States
(12) Patent Application Publication
(10) Pub. No.: US 2011/0097881 A1
(43) Pub. Date: Apr. 28, 2011

(54) Method of Forming Mono-Crystalline Germanium or Silicon Germanium

(75) Inventors: Wilfried Vandervorst, Mechelen (BE); Gang Wang, Leuven (BE)

(73) Assignees: IMEC, Leuven (BE); KATHOLIEKE UNIVERSITEIT LEUVEN, K.U. LEUVEN R&D, Leuven (BE)

(21) Appl. No.: 12/910,348

(22) Filed: Oct. 22, 2010

(30) Foreign Application Priority Data
Oct. 23, 2009 (EP) 09173972.2

(51) Int. Cl. H01L 21/20

(52) U.S. Cl. 438/486; 257/E21.09

(57) ABSTRACT

A method is presented for forming mono-crystalline germanium or silicon germanium in a trench. In an embodiment, the method comprises providing a substrate comprising at least one active region that is adjacent to two insulating regions, forming in the active region a trench having a width of less than 100 nm, and forming in the trench a fill layer at a temperature of less than 450° C. that comprises germanium or silicon germanium and substantially fills the trench. The method further comprises heating the fill layer to a temperature sufficient to substantially melt the fill layer and allowing re-crystallization of the substantially melted fill layer, thereby forming mono-crystalline germanium or silicon germanium in the trench. In an embodiment, the method further comprises forming a mono-crystalline germanium or silicon germanium fin by removing at least a portion of the insulating regions. The mono-crystalline fin may be comprised in a fin field-effect-transistor (finFET).

### CROSS-REFERENCE TO RELATED APPLICATIONS

This application claims priority to European Patent Application No. 09173972.2 filed Oct. 23, 2009, the contents of which are incorporated by reference herein in their entirety.

### TECHNICAL FIELD OF THE INVENTION

The present invention is related to the field of germanium or silicon germanium FinFET devices and methods for forming the same. More specifically, the invention relates to epitaxial growth of mono-crystalline germanium or silicon germanium in trenches provided in a substrate. In particular, the present invention is directed to an improved method of forming mono-crystalline germanium or silicon germanium fin structures on a substrate.

### BACKGROUND OF THE INVENTION

The scaling down of planar bulk complementary metal-oxide-semiconductor (CMOS) devices has become a major challenge in the semiconductor industry. While the sizes of many devices has been reduced (and corresponding performances have been improved), device architectures below the 90 nm range remain a challenge.

Multi-gate field effect transistors (MUGFET), also often referred to as fin-based semiconductor devices or FinFETs, are one of the promising candidates for further scaling down to 32 nm or less. MUGFETs use a three-dimensional architecture in which the gate electrode of the MUGFET is wrapped around a thin semiconductor fin. This design allows for improvement of gate control and a reduction of short-channel effects through the use of multiple gates.

In addition to the MUGFET, the silicon FinFET has also emerged as one of the promising candidates for highly scaled MOSFETs. However, for silicon CMOS devices that are scaled into deep sub-micrometer regime, new materials with higher channel mobility are needed to enhance the performance of these devices.

It is known in the art that germanium MOSFETs have higher effective electron and hole mobility than silicon MOSFETs.

A discussion of manufacturing crystalline germanium finFETs is provided in “P-Channel Germanium FinFET based on Rapid Melt Growth”, IEEE Electron Device Letters, Vol. 28, No. 7, July 2007, pp 637-639, by Feng J. et al., which describes the manufacture of crystalline germanium FinFETs based on the so-called rapid-melt-growth method. According to Feng, the method involves: (a) depositing amorphous germanium onto silicon substrate; (b) patterning amorphous germanium into fins using lithography and photoresist ashing followed by a reactive ion etch; (c) encapsulating the germanium fins by depositing a conformal low-temperature oxide (LTO) layer (microcrucible); (d) heating up the formed structure via rapid thermal processing (at 940° C.) to melt the germanium; (e) cooling down the structure; and (f) removing the LTO microcrucibles by etching with HF.

The described method is, however, characterized by a relatively large number of steps. Additionally, in the described method, the formed germanium fins are reported to comprise crystalline defects, in particular at the Ge/Si interface. Moreover, the disclosed germanium fins have a fin width above 130 nm.

Single-crystal germanium pillars with nanowire dimensions as well as germanium-on-insulator (GeOI) structures are discussed in “Rapid Melt Growth of Germanium Crystals with Self-Aligned Microcrucibles on Si Substrates”, Journal of The Electrochemical Society, 152 (8), G688-G693 (2005), by Liu Y. et al. Liu discusses the manufacture of both germanium pillars and GeOI structures.

With respect to the germanium pillars, Liu discloses that the manufacture of germanium pillars involves (a) depositing a thick amorphous germanium film onto a silicon substrate, (b) using lithography and a anisotropic reactive ion etch to form germanium pillars, (c) stripping the resist, and (d) depositing a conformal low-temperature SiO₂ (LTO) layer to cover the pillars.

With respect to the GeOI structures, Liu discloses that the manufacture of GeOI structures involves (1) forming an insulator layer on a Si(100) substrate, and (b) patterning the insulator layer to open some seeding windows. The insulator layer may be silicon dioxide, silicon nitride, or other materials. According to Liu, the manufacture further involves (c) depositing amorphous germanium by non-selective deposition on a very thin silicon layer previously formed on the insulator layer, (d) patterning the amorphous germanium film to the desired shape using photolithography and RIE, and (e) depositing a conformal LTO layer to cover the patterned germanium.

In the manufactures of both the germanium pillars and the GeOI structures, Liu teaches that the wafers onto which either the germanium pillars or the GeOI structures were manufactured may be loaded into a rapid thermal processing (RTP) chamber and heated up to 940° C. to melt the germanium. In both cases, the LTO layer works as a microcrucible to hold the germanium liquid and prevent it from flowing randomly.

However, the methods disclosed by Liu suffer from several drawbacks, one of which is a rather complex implementation. Also, the disclosed methods are inherently limited by the performance of patterning processes (e.g., photolithography and RIE).

U.S. Pat. No. 6,180,480, issued to Economikos et al., discloses a process for making a trench capacitor in a high-aspect-ratio trench in a silicon wafer. Economikos discloses that the process allows completely filling a trench formed in a substrate with a fill material comprising germanium or silicon germanium. The described method is claimed to be suitable for trenches having widths on the order of 200 nm.

Despite the progress in the art, there is still need for a method of forming high quality mono-crystalline germanium or silicon germanium in a trench having a width narrower than 100 nm. Additionally, a method that involves fewer steps than the processes known in the art is desired.

Other advantages of the invention will be immediately apparent to those skilled in the art from the following description.

### SUMMARY OF THE INVENTION

A method is presented for forming mono-crystalline germanium or silicon germanium in a trench. According to an embodiment, the method comprises providing a substrate comprising at least one active region. The at least one active region comprises a semiconductor material and is adjacent to two insulating regions. The method further comprises forming in the at least one active region a trench having a width of less than 100 nm such that sidewalls of the trench are formed by the insulating regions and the semiconductor material is exposed at the bottom of the trench. The method further comprises forming in the trench a fill layer at a temperature of less than about 450° C. The fill layer comprises germanium or silicon germanium and substantially fills the trench. The method additionally comprises heating the fill layer to a temperature sufficient to substantially melt the fill layer, thus producing a substantially melted fill layer, and allowing re-crystallization of the substantially melted fill layer, thereby forming mono-crystalline germanium or silicon germanium in the trench.

According to another aspect of the invention, a method of forming a mono-crystalline germanium or silicon germanium fin structure is presented. According to an embodiment, the method comprises providing a substrate comprising at least one active region. The at least one active region comprises a semiconductor material and is adjacent to two insulating regions. The method further comprises forming in the at least one active region a trench having a width of less than 100 nm such that sidewalls of the trench are formed by the insulating regions and the semiconductor material is exposed at the bottom of the trench. The method further comprises forming in the trench a fill layer at a temperature of less than about 450° C. The fill layer comprises germanium or silicon germanium and substantially fills the trench. The method additionally comprises heating the fill layer to a temperature sufficient to produce a substantially melted fill layer, and allowing re-crystallization of the substantially melted fill layer, thereby forming mono-crystalline germanium or silicon germanium in the trench. The method additionally comprises forming a mono-crystalline germanium or silicon germanium fin by removing at least a portion of the insulating regions. The method may further comprise forming a fin field-effect transistor that comprises the mono-crystalline germanium or silicon germanium fin.

In some embodiments, the semiconductor material may comprise silicon, and the insulating regions may be in the form of a Shallow Trench Isolation and comprise one or more of silicon oxide and silicon nitride.

In some embodiments, the method may further comprise cleaning a surface of the substrate before forming the trench. Cleaning a surface of the substrate may comprise one or more of a performing a wet cleaning on the surface of the substrate, performing a diluted hydrogen fluoride dip, and removing native oxide from the surface of the substrate. Cleaning a surface of the substrate may be performed after loading the substrate into a process chamber, and the cleaning may comprise an in-situ cleaning in a hydrogen ambient. One or both of (i) cleaning a surface of the substrate and (ii) forming the trench may be performed in a process chamber.

In some embodiments, the method may further comprise performing an in-situ anneal before forming the trench.

In some embodiments forming the trench may comprise forming the trench by one or more of in-situ etching, chemical etching, reactive ion etching, and chemical vapor phase etching.

In some embodiments, forming the fill layer may comprise forming the fill layer by one of selective epitaxial growth, chemical vapor deposition, and exposure to one or more precursors. Forming the fill layer may be performed at a temperature between 100° C. and 450° C.

In some embodiments, heating the fill layer may comprise heating the fill layer by one of a laser anneal technique and a flash anneal technique. If the fill layer comprises silicon germanium, heating the fill layer may comprise heating the fill layer to a temperature between 850° C. and 1500° C. If the fill layer comprises germanium, heating the fill layer may comprise heating the fill layer to a temperature between 850° C. and 950° C. Heating the fill layer may comprise heating the fill layer in an inert ambient. Heating the fill layer may comprise heating the fill layer for less than 500 milliseconds.

In some embodiments, allowing re-crystallization of the substantially melted fill layer may comprise one or both of cooling the substantially melted fill layer and allowing re-crystallization by epitaxial growth.

In some embodiments, the method may further comprise performing a chemical mechanical polish after forming the fill layer.

In some embodiments, removing at least a portion of the insulating regions may comprise etching the insulating regions. In some embodiments, the method may further comprise forming a fin field-effect transistor comprising the mono-crystalline germanium or silicon germanium fin.

### BRIEF DESCRIPTION OF THE DRAWINGS

All figures/drawings are intended to illustrate some aspects and embodiments of the present invention. Devices are depicted in a simplified way for the purpose of clarity. Not all alternatives and options are shown, and the invention is not limited to the content of the given drawings.

FIG. 1 depicts scanning electron microscope (SEM) images illustrating the surface migration of germanium out of the trenches at an operating temperature of 600° C. while using a prior art method.

FIG. 2 is a cross-sectional transmission electron microscope (TEM) image illustrating twin defects present in a germanium fill layer formed in a trench at 430° C. while using a prior art method.

FIG. 3 schematically illustrates a method in accordance with an embodiment of the present invention.

FIG. 4 depicts SEM images illustrating a germanium fill layer formed in trenches having a width of 20 nm using a method in accordance with an embodiment of the present invention.

FIG. 5 depicts, in FIG. 5(a), a first cross-sectional TEM image illustrating twin defects present in a germanium fill layer heated at 800° C. according to a prior art method, and, FIG. 5(b), a second cross-sectional TEM image showing an absence of twin defects in germanium heated at 900° C. according to a method in accordance with the present invention.

### DETAILED DESCRIPTION OF THE INVENTION

In the context of the present invention, the term “mono-crystalline” is meant to designate single-crystalline form of a material. The terms “trench”, “active region” and “insulating region” are herewith meant to have their commonly accepted meaning in the art. More specifically, an active region or an active area is comprised or formed of a semiconductor material and designates the physical part of a substrate on/in which the corresponding devices (such as e.g. transistors, resistors and capacitors) which perform computing and storage operations are defined. An insulating (isolation) region/area or a field oxide area is comprised or formed of an insulator (dielectric material) and serves to electrically isolate two or more devices on the same substrate. A trench is meant to refer to a recessed area having a rectangular cross-section. By the expression “the semiconductor material is exposed at the bottom of the trench” it is meant herein that the bottom of the trench is comprised or formed of the semiconductor material.

The invention will now be discussed in detail with reference where appropriate to the accompanying drawings.

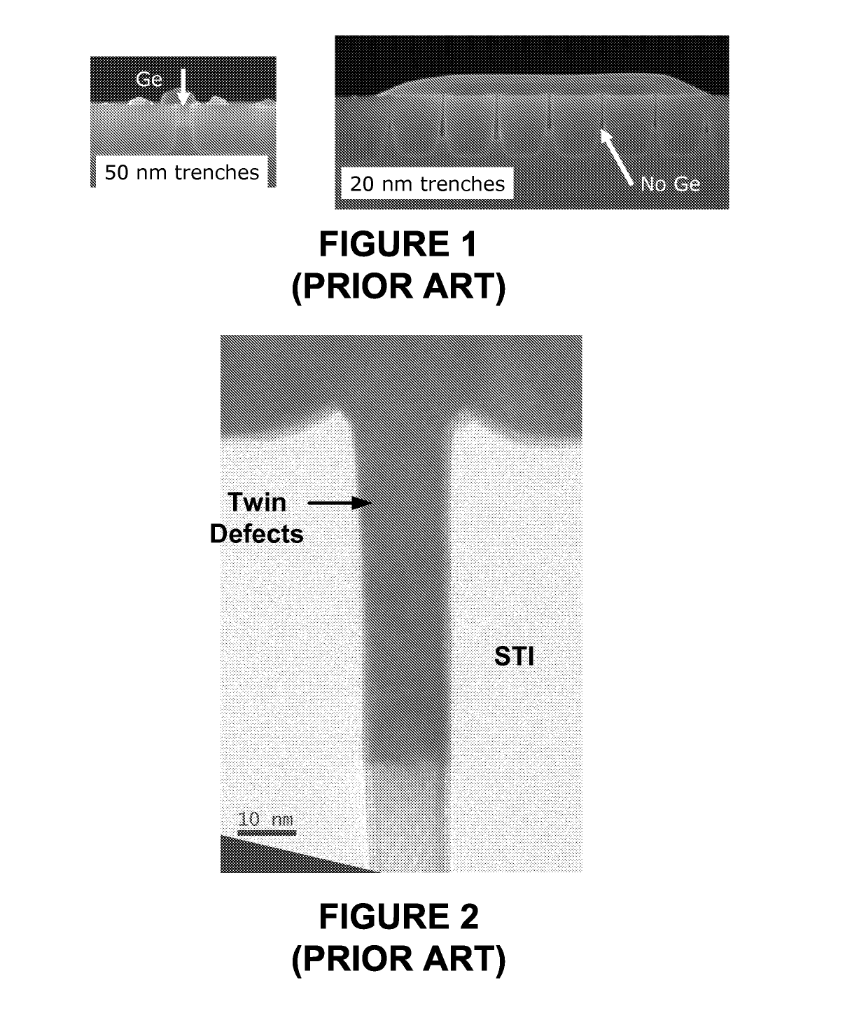

Currently available techniques to fill trenches are not suitable to form high-quality mono-crystalline material in trenches having high aspect ratios or those having a width of less than 100 nm, such as trenches having a width of 50 nm. FIG. 1 shows an attempt to fill trenches having a width below 100 nm with germanium according to a prior art method. In particular, FIG. 1 depicts scanning electron microscope (SEM) images illustrating the surface migration of germanium out of the trenches at an operating temperature of 600° C. while using a prior art method.

As can be seen from FIG. 1, the traditional methods are hampered by the poor crystalline quality of the germanium grown in the narrow trenches. An example of the defects resulting from prior art methods is shown in FIG. 2. In particular, FIG. 2 is a cross-sectional transmission electron microscope (TEM) image illustrating twin defects present in a germanium fill layer formed in a trench at a temperature of 430° C. while using a prior art method. The germanium twin defects shown in FIG. 2 are one type of defect that can occur in the germanium crystals grown in narrow trenches using traditional methods.

These challenges of the traditional methods are exacerbated at higher growth temperatures (i.e. of higher than about 600° C.) where the geometry of the trenches further hampers the growth of germanium. In particular, it has been discovered that the phenomenon of surface migration at least partly drives the germanium out of the (narrow) trenches. In some cases using known methods in very narrow trenches (e.g., a width of less than about 20 nm) at higher growth temperatures, no growth is observed at all.

Accordingly, an improved method of forming mono-crystalline germanium or silicon germanium in a trench is desired that would reduce or eliminate the drawbacks of the methods know in the art. In particular, it is desirable to improve the poor crystalline quality of the germanium or silicon germanium grown in narrow trenches at lower growth temperatures. In the framework of the present invention, it is also desirable to improve the quality of germanium or silicon germanium fill layers formed in very narrow trenches at higher growth temperatures.

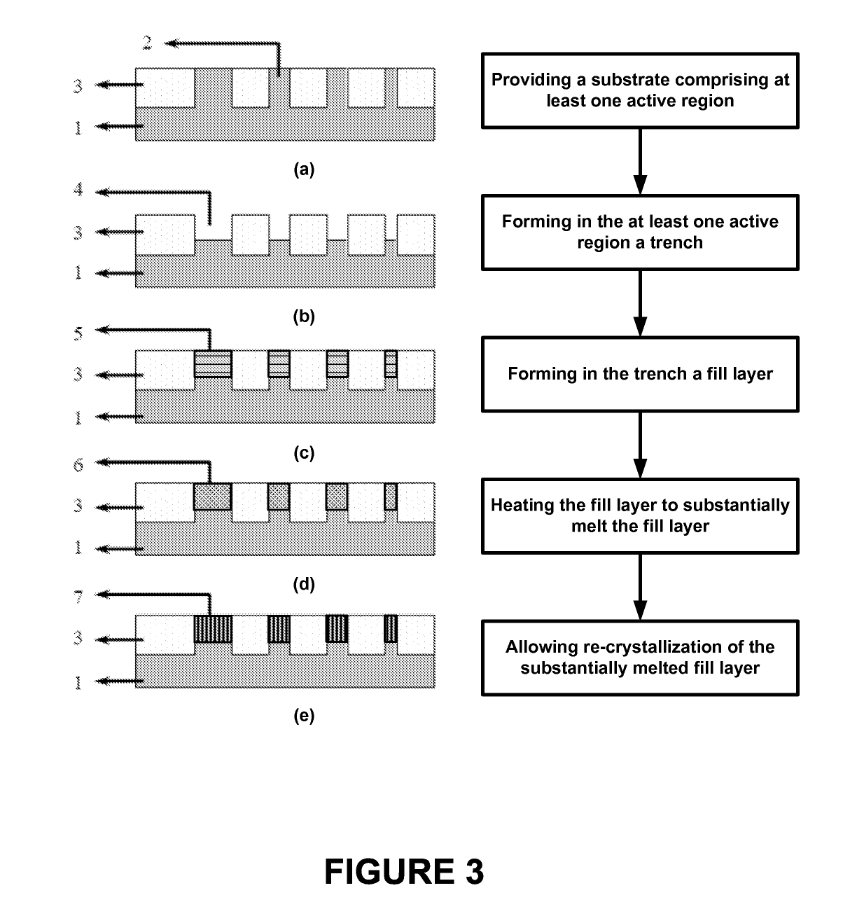

FIG. 3 schematically illustrates a method in accordance with an embodiment of the present invention. In FIG. 3, reference 1 designates a substrate, 2 designates at least one active region, 3 designates an insulating region, 4 designates one trench, 5 designates one fill layer comprising germanium or silicon germanium, 6 designates one melted fill layer, and 7 designates mono-crystalline germanium or silicon germanium obtained after re-crystallization of one melted fill layer. As shown, the substrate comprises a silicon oxide/silicon shallow trench isolation (STI) type of insulating region/substrate system. The STI substrate may comprise at least one active area 2 comprising a semiconductor material surrounded by (adjacent to) a plurality of insulating regions 3.

According to FIG. 3, the method begins at (a) where a substrate 1 is provided comprising at least one active region 2, wherein the at least one active region 2 comprises a semiconductor material and is adjacent to two insulating regions 3. At (a), the substrate 1 is shown comprising an active region 2 as well as a plurality of insulating regions 3. As shown, the active region 2 is adjacent to two of the insulating regions 3.

In the context of the method, any substrate 1 compatible with semiconductor manufacturing may be used. Suitable substrates 1 for use herein may be easily identified by those skilled in the art. Typically, substrates 1 for use herein include any substrate 1 compatible with semiconductor manufacturing and comprising at least one semiconductor layer as a top layer. Typical examples of suitable substrate 1 for use herein comprise, but are not limited to, bulk semiconductor materials (such as silicon, germanium, and silicon germanium), and silicon-on-insulator (SOI) and germanium-on-insulator (GeOI) stacked substrates comprising a layer of a semiconductor material overlying an insulating support substrate such as quartz or glass. In an embodiment of the method, the substrate 1 may be a silicon substrate. In an embodiment of the method, the substrate 1 may be a patterned substrate. Methods and techniques for providing such a patterned substrate 1 comprising at least one active region 2, wherein the at least one active region 2 comprises a semiconductor material and is adjacent to two insulating regions 3, will be easily apparent to those skilled in the art.

In the context of the method, the term “insulating region” 3 is meant to have its commonly accepted meaning in the art. In an embodiment, the insulating regions 3 may comprise a dielectric layer of silicon oxide (Si0₂), silicon nitride (Si₃N₄) or mixtures thereof. Other suitable materials will be easily identified by those skilled in the art. In particular, the insulating regions 3 may be in the form of a Shallow Trench Isolation (STI) wherein the insulating layer comprises silicon oxide (SiO₂).

At the completion of (a), and before the method continues at (b), in some embodiments the method may further comprise loading the substrate 1 into a process chamber (or reactor) for further processing. Alternately or additionally, before the method continues at (b), in some embodiments the method may further comprise cleaning a surface of the substrate 1 before forming the trench 4, as described below. In an embodiment, the cleaning step is provided so as to remove native oxide from the surface of the substrate 1. Suitable ways of removing native oxide from the surface of the substrate 1 will be easily identified by those skilled in the art. Examples of processes for cleaning a surface of the substrate 1 include performing a wet cleaning step of the surface of the substrate 1, using a diluted HF dip, such as a 2% HF solution, and performing an in-situ cleaning in a hydrogen (H₂) ambient. The cleaning may be performed before the optional step of loading the substrate 1 into a process chamber. Alternatively, the cleaning may be performed once the substrate 1 is loaded in the process chamber.

Optionally, the method may further comprise a step of performing an in-situ annealing step of the substrate 1 so as to further remove native oxide and contaminants from the surface of the substrate 1. The anneal step is performed by injecting a carrier gas in the reaction chamber. Hydrogen may be employed as a carrier gas and the annealing step may be performed at a temperature between 800° C. and 1000° C., or even between 800° C. and 850° C. The pressure in the reaction chamber during said first anneal step may be about 10 Torr. The in-situ anneal step is performed to remove further native oxide and/or surface contaminants before etching the trench 4.

In some embodiments, this additional step may be performed once the substrate 1 is loaded in the process chamber. An example temperature range for such an annealing step is about 800° C. to about 850° C.

According to FIG. 3, the method continues at (b) where a trench 4 is formed in the at least one active region 2 having a width of less than 100 nm. As shown in (b), the sidewalls of the trench 4 are formed by the insulating regions 3, and the semiconductor material of the at least one active region 2 is exposed at the bottom of the trench 4. Any techniques known in the art for the formation of trenches 4 may be used in the context of the present invention. Suitable techniques include, but are not limited to, in-situ etching, chemical etching, reactive ion etching, chemical vapor phase etching, and combinations thereof. However, the invention is not so limited.

In some embodiments of the method, the trench 4 may have a width less than 80 nm, less than 60 nm, less than 50 nm, less than 30 nm, or even a width of about 20 nm. The depth-to-width aspect ratio of the trench 4 may, in some embodiments, be more than about 2, more than about 5, more than about 10, or even more than about 20.

In some embodiments, the substrate 1 may be in the form of a shallow trench isolation (STI) type of substrate system. As STI system/technology is well known in the art, no further details will be provided hereinafter as to its manufacture. The use of an STI type of insulating region 3/substrate system allows at least one trench 4 to be pre-formed in the active region. However, a step of removing material so as to free the at least one trench 4 and make it suitable/ready to receive a fill layer (as described below) may be required.

In an embodiment, the STI type of insulating region 3/substrate system comprises a silicon-comprising patterned substrate 1 (or layer) provided with at least one silicon-comprising active region 2 adjacent to two silicon oxide-comprising insulating regions (or layers) 3.

The trench 4 may be created in-situ in the same reaction/process chamber where the formation of the fill layer is performed, as described below. As an example, in one embodiment the at least one active area may be made of silicon and the insulating regions 3 may be made of silicon oxide. In this embodiment, the trench 4 may be created by in-situ vapor hydrogen chloride (HCl) etch in the epitaxial reactor of silicon. The etch may be a selective etch towards silicon oxide.

An example etch sequence is now described. In one embodiment, after an annealing step has been completed, in-situ etching of the semiconductor material is performed in the at least one active region 2, thereby forming trenches 4 in the semiconductor material having the insulation regions 3 as side-walls. In a particular embodiment wherein a silicon/silicon oxide STI substrate is employed, the trenches 4 have sidewalls constituted of silicon oxide and a bottom constituted of silicon. The etching gas is injected in the reaction chamber. The etching gas may be HCl vapor, or other chlorine comprising compounds. Advantageously, the etching step does not create any damage to the insulating regions 3 (e.g. silicon oxide).

In the embodiment, the etching step may be performed in such a way that the semiconductor material that was previously comprised into the trench 4 is progressively etched to such an extent that the depth the resulting trench 4 (defined by the bottom of the trench 4) is smaller than the depth defined by the lower level of the adjacent insulating regions 3 (e.g. silicon oxide), as is shown in (b). Alternatively, the depth of the trench 4 may be substantially equal to the depth defined by the lower level of the adjacent insulating regions 3. In any case, the semiconductor material (e.g. silicon) will be exposed at the bottom of the trench 4 which incidentally implies that the bottom of the trench 4 is comprised of the semiconductor material used.

In the embodiment, the etching step may be performed with a temperature of the substrate between 800° C. and 900° C. The pressure in the reaction chamber may be between 10 Torr and 40 Torr. In the embodiment, during the etching step the HCl partial pressure may be between 0.01 Torr and 0.1 Torr, preferably about 0.04 Torr.

According to FIG. 3, the method continues at (c) where a fill layer 5 comprising germanium or silicon germanium is formed in the trench 4 at a temperature of less than 450° C. That is, the fill layer 5 is formed in the trench 4 while the surrounding temperature is less than 450° C. For example, if the fill layer 5 is formed while the substrate 1 is in an epitaxial apparatus (epi-reactor) chamber, the temperature inside the epi-reactor chamber may be 450° C. The fill layer 5 may substantially fill the trench 4. Suitable techniques to form a fill layer 5 for use in the method of the invention will be easily apparent to those skilled in the art. In some embodiments, forming the fill layer 5 may comprise forming the fill layer 5 by a Chemical Vapor Deposition (CVD) technique. CVD may be performed in hydrogen (H₂) or nitrogen (N₂) ambient. However, other inert gases, an example of which is argon (Ar) may alternatively be used. Other suitable techniques for forming the fill layer 5 include, but are not limited to gas-phase molecular epitaxy, gas-phase chemical vapor deposition technique, or Reduced Pressure Chemical Vapor Deposition (RPCVD). The CVD may be performed at a substrate temperature of less than about 450° C., for example about 430° C.

In some embodiments, forming the fill layer 5 may comprise using precursors such as, for example, a combination of GeₓH₂ₓ₊₂ and Si_{y}H_{2y+2} or GeₓSi₁₋ₓH₂ₓ₊₂ in the context of the invention of the method according to the invention. As will be apparent to those skilled in the art, exposure of the substrate 1 to one or more volatile or non-volatile germanium or silicon germanium precursors may take place while performing deposition by CVD technique. Example germanium precursors for use in the method of the invention include, but are not limited to, germane (GeH₄) and/or digermane (Ge₂H₆) for depositing germanium. However, other germanium precursors of higher orders, such as e.g. Ge₃H₈ and other GeₓH₂ₓ₊₂ related derivatives (such as GeₓH_{y}Cl_{2x+2-y}), may be used in the context of the method according to the invention. In some embodiments, forming the fill layer 5 may comprise a selective deposition technique, in which only a portion of the substrate, such as the trench 4 is exposed to the precursors.

In some embodiments, forming the fill layer 5 may comprise selective epitaxial growth, in which the fill layer 5 grows selectively on the semiconductor substrate at the bottom of the trench 4 and does not grow on the insulator material, on the lateral walls of the trench 4, or on the top surface of the substrate 1. In some embodiments, this step may be performed in an epitaxial apparatus (epi-reactor), as will be apparent to the skilled person. Characteristics such as deposition pressure, gas flows, precursor concentrations, partial pressure, and atmosphere in the epi-reactor, may be adjusted to tune the process for optimal deposition/forming rate and optimal trench filling.

Example values for the partial pressure may be between 0.02 Torr and 0.3 Torr. The atmosphere may vary depending on the type of CVD used. For example, Atmospheric Pressure Chemical Vapor Deposition (APCVD) may be performed at atmospheric pressure (about 760 Torr), and Reduced Pressure Chemical Vapor Deposition (RPCVD) may be performed at lower than atmospheric pressure. Both CVD techniques may be equally used in the method of the invention.

In some embodiments, the temperature used to form the fill layer 5 into the trench 4 (in some cases, the temperature in the epi-reactor chamber) may be between (about) 100° C. and (about) 450° C., or between (about) 350° C. and (about) 445° C., or between (about) 400° C. and (about) 445° C., or even between 420° C. and 440° C. It has indeed been surprisingly discovered that performing the deposition step at a temperature of less than (about) 450° C. prevents or at least reduces germanium or silicon germanium surface migration out of the trenches 4, as described above in connection with FIG. 1.

At the completion of (c), as shown in FIG. 3, the method may in some embodiments comprise a step of performing a Chemical Mechanical Polishing (CMP). The CMP may be performed so as to obtain a smooth and even substrate surface 1 and/or to remove any excess material present out of the trench 4.

According to FIG. 3, the method continues at (d), where the fill layer 5 is heated to a temperature sufficient to substantially melt the fill layer 5, resulting in a melted fill layer 6. In an embodiment, the temperature may be close to (or greater than) the melting temperature of the fill-layer material, namely germanium or silicon germanium depending on the particular case. The heating temperature may be controlled so as to be maintained well below the melting temperature of the substrate 1 used. Accordingly, during the heating step for use in the method of the invention, none of the adjacent insulating regions 3 or the underlying substrate 1 will be melted. The temperature to which the fill layer is heated may, in some embodiments, be the same as the temperature of the substrate. In others, it may not be.

If the fill layer 5 comprises germanium, the fill layer 5 may, in some embodiments, be heated to a temperature between 850° C. and 950° C., or between 900° C. and 950° C., or even between 920° C. and 940° C.

If the fill layer 5 comprises silicon germanium, the fill layer 5 may, in some embodiments, be heated to a temperature between 850° C. and 1500° C., or between 850° C. and 1400° C. Typically, the temperature to which the fill layer 5 comprising silicon germanium is heated will depend upon the germanium concentration of the corresponding silicon germanium material.

In some embodiments of the invention, the duration of the step of heating the fill layer 5 comprising germanium or silicon-germanium may be less than 500 milliseconds, or may be between 1 nanosecond and 100 milliseconds, or even between 20 nanoseconds and 100 milliseconds. The heating step may in some embodiments be characterized as a rapid melting step. Keeping the duration of the heating step below 500 milliseconds may, in some cases, contribute to reducing surface migration that may drive the germanium or silicon germanium out of the trenches 4. Additionally, a duration below 500 milliseconds may also contribute to reducing any crystalline defects (such as twin defects or dislocations) in the fill layer 5 formed in step (c) described above.

In some embodiments, heating the fill layer 5 may comprise heating the fill layer 5 by a laser anneal or flash anneal (flash heating) technique. Laser anneal and flash anneal are techniques well known to those skilled in the art. In other embodiments, heating the fill layer 5 may comprise heating the fill layer 5 by an appropriate (flash) microwave anneal/heating. In some embodiments, the temperature provided by the laser or the flash heating may be between (about) 850° C. and (about) 950° C. or between 850° C. and 1500° C., depending on whether the fill layer 5 comprises germanium or silicon germanium respectively. In order to reduce the thermal stress of the laser or flash heating, the laser or flash heating step may be performed after reaching a chuck temperature of 250° C.

Heating the fill layer 5 may comprise selectively heating the fill layer 5, such that heat is selectively applied to the fill layer 5 present into the trench 4, or instead may comprise non-selectively heating the fill layer 5, such that both the substrate 1 (and the insulating regions 3) and the fill layer 5 are subjected to the heating step.

According to an embodiment in which a laser anneal is used, the laser may scan the substrate 1 and/or the fill layer 5 at a laser scan speed of (about) 75 mm/s.

Alternatively, the laser scan speed can be higher up to 300 mm/s or 450 mm/s. The temperature of the laser anneal may be selected to be any of 800° C., 850° C., 900° C. or 950° C. in N₂ ambient, depending on the specific composition of the fill layer 5. In any case, the temperature may be sufficient to completely melt the germanium or silicon germanium comprising fill layer 5, thereby forming a melted fill layer 6. Before performing the laser anneal the chuck temperature may be brought to 250° C. and kept constant during the laser anneal.

According to FIG. 3, the method continues at (e). At (e), the method comprises allowing re-crystallization of the substantially melted fill layer 6, thereby forming mono-crystalline germanium or silicon germanium 7 in the trench 4.

In some embodiments, re-crystallization of the melted fill layer 6 may comprise appropriately cooling the melted fill layer 6 obtained in step (c), preferably down to room (chamber or reactor ambient) temperature. In some embodiments, mono-crystalline germanium or silicon germanium 7 may be formed by epitaxial re-crystallization or re-growth. In an embodiment, such re-crystallization (or epitaxial re-growth) may take place during the temperature ramp-down from the laser anneal temperature to the chuck temperature and then further down to room temperature in N₂ ambient.

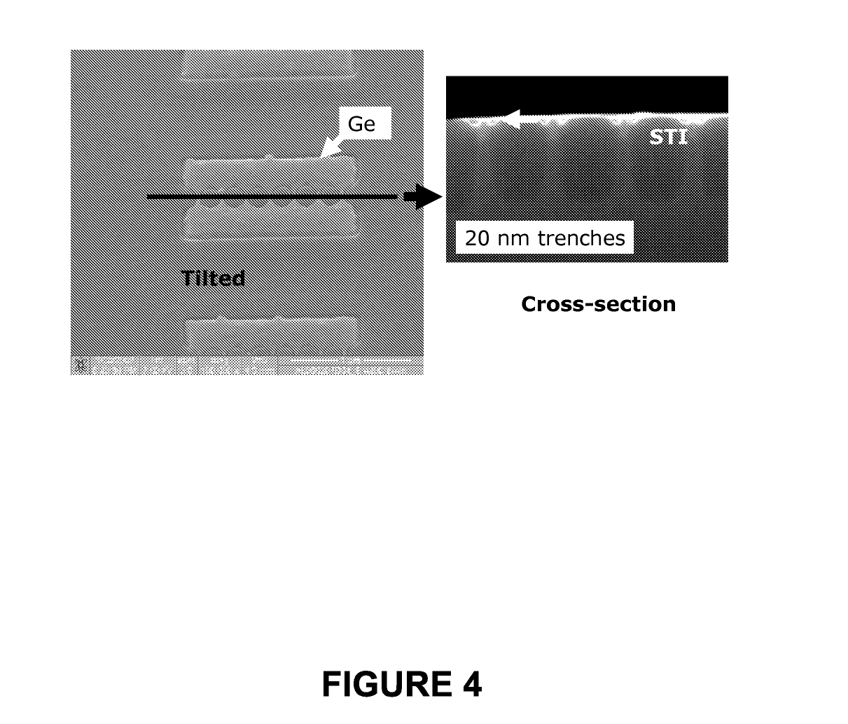

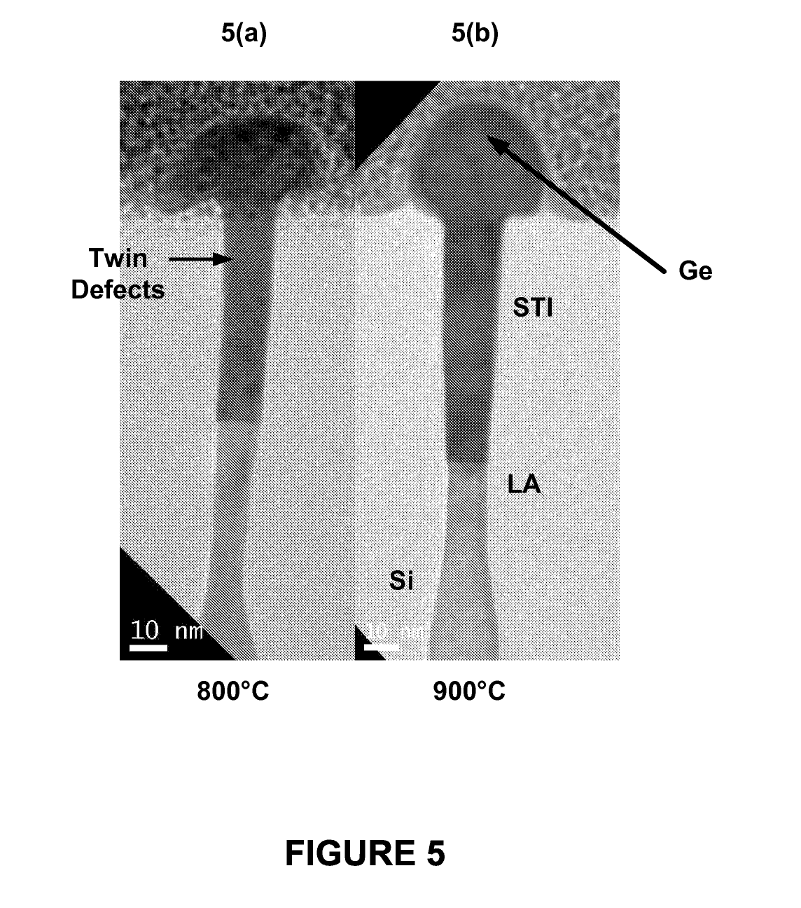

The method has thus been described. Imaging measurements illustrate the improvement over traditional methods. In particular, FIG. 4 depicts SEM images illustrating a germanium fill layer formed in trenches having a width of 20 nm using a method in accordance with an embodiment of the present invention. Further, FIG. 5 depicts, in FIG. 5(a), a first cross-sectional TEM image illustrating twin defects present in a germanium fill layer heated at 800° C. according to a prior art method, and, FIG. 5(b), a second cross-sectional TEM image showing an absence of twin defects in germanium heated at 900° C. according to a method in accordance with the present invention. In other words, measurements performed on the mono-crystalline germanium or silicon germanium obtained with the described method show excellent crystalline quality, and incidentally confirmed absence of any germanium twin defects. The method according to the present invention allows using the available STI (Shallow Trench Isolation) process technology. In that context, the STI isolation regions have the additional advantage of providing good electrical isolation between the adjacent devices.

The method may be used to form germanium or silicon germanium fins in pre-defined trenches in the substrate instead of forming the fins by patterning of a germanium or silicon germanium layer on top of a semiconductor substrate, as in typical methods. This has the additional advantage of defect dislocation trapping mechanism known to occur in narrow width (for example, less than 100 nm) trenches, which leads to a better crystalline material. Further, the method of the invention advantageously allows the integration of different materials (e.g. germanium or silicon germanium) on a single silicon wafer. The formation of such fins may comprise removing at least a portion of the insulating regions. The insulating regions may be removed using any of the suitable etching techniques described above or known in the art.

According to another aspect, the present invention is directed to the use of a method as described above for the manufacturing of a semiconducting device. The method of the invention may be used in the manufacturing of well known semiconductor devices, such as e.g. CMOS devices, Buried quantum well devices, MUGFET (multiple gate FET) devices. The method of the invention may find particular use in the manufacture of Field Effect Transistors, and more preferably for the manufacture of a FinFET device. More specifically, the method may find a particularly preferred use in the manufacture of fin structures, as described above, for use in the manufacture of FinFET devices. According to still another aspect, the present invention relates to a FinFET device comprising a germanium or silicon germanium fin structure obtainable by a method as described above.

What is claimed is:

1. A method of forming mono-crystalline germanium or silicon germanium in a trench, comprising:
providing a substrate comprising at least one active region, wherein the at least one active region comprises a semiconductor material and is adjacent to two insulating regions;
forming in the at least one active region a trench having a width of less than 100 nm, wherein sidewalls of the trench are formed by the insulating regions and the semiconductor material is exposed at the bottom of the trench;
at a temperature of less than 450° C., forming in the trench a fill layer that comprises germanium or silicon germanium and substantially fills the trench;
heating the fill layer to a temperature sufficient to produce a substantially melted fill layer; and
allowing re-crystallization of the substantially melted fill layer, thereby forming mono-crystalline germanium or silicon germanium in the trench.

2. The method of claim 1, wherein the semiconductor material comprises silicon.

3. The method of claim 1, further comprising cleaning a surface of the substrate before forming the trench.

4. The method of claim 3, wherein cleaning a surface of the substrate comprises one or more of:
(i) performing a wet cleaning on the surface of the substrate,
(ii) performing a diluted hydrogen fluoride dip, and
(iii) removing native oxide from the surface of the substrate.

5. The method of claim 3, wherein cleaning a surface of the substrate is performed after loading the substrate into a process chamber, and wherein the cleaning comprises an in-situ cleaning in a hydrogen ambient.

6. The method of claim 3, wherein one or both of (i) cleaning a surface of the substrate and (ii) forming the trench is performed in a process chamber.

7. The method of claim 1, further comprising performing an in-situ anneal before forming the trench.

8. The method of claim 1, wherein forming the trench comprises forming the trench by one or more of in-situ etching, chemical etching, reactive ion etching, and chemical vapor phase etching.

9. The method of claim 1, wherein forming the fill layer comprises forming the fill layer by one of selective epitaxial growth, chemical vapor deposition, and exposure to one or more precursors.

10. The method of claim 1, wherein forming the fill layer at a temperature below 450° C. comprises forming the fill layer at a temperature between 100° C. and 450° C.

11. The method of claim 1, wherein heating the fill layer comprises heating the fill layer by one of a laser anneal technique and a flash anneal technique.

12. The method of claim 1, wherein the fill layer comprises silicon germanium, and wherein heating the fill layer comprises heating the fill layer to a temperature between 850° C. and 1500° C.

13. The method of claim 1, wherein the fill layer comprises germanium, and wherein heating the fill layer comprises heating the fill layer to a temperature between 850° C. and 950° C.

14. The method of claim 1, wherein heating the fill layer comprises heating the fill layer in an inert ambient.

15. The method of claim 1, wherein heating the fill layer comprises heating the fill layer for less than 500 milliseconds.

16. The method of claim 1, wherein allowing re-crystallization of the substantially melted fill layer comprises one or both of (i) cooling the substantially melted fill layer and (ii) allowing re-crystallization by epitaxial growth.

17. The method of claim 1, wherein the insulating regions are in the form of a Shallow Trench Isolation and comprise one or more of silicon oxide and silicon nitride.

18. The method of claim 1, further comprising performing a chemical mechanical polish after forming the fill layer.

19. A method of forming a mono-crystalline germanium or silicon germanium fin structure, comprising:
providing a substrate comprising at least one active region, wherein the at least one active region comprises a semiconductor material and is adjacent to two insulating regions;
forming in the at least one active region a trench having a width of less than 100 nm, wherein sidewalls of the trench are formed by the insulating regions and the semiconductor material is exposed at the bottom of the trench;
at a temperature of less than 450° C., forming in the trench a fill layer that comprises germanium or silicon germanium and substantially fills the trench;
heating the fill layer to a temperature sufficient to produce a substantially melted the fill layer;
allowing re-crystallization of the substantially melted fill layer, thereby forming mono-crystalline germanium or silicon germanium in the trench; and
forming a mono-crystalline germanium or silicon germanium fin by removing at least a portion of the insulating regions.

20. The method of claim 19, wherein removing at least a portion of the insulating regions comprises etching the insulating regions.

21. The method of claim 19, further comprising forming a fin field-effect transistor comprising the mono-crystalline germanium or silicon germanium fin.
